(19) United States
(12) Patent Application Publication
(10) Pub. No.: US 2006/0249201 A1
(43) Pub. Date: Nov. 9, 2006

(54) Rechargeable dye sensitized solar cell

(75) Inventor: Nabil M. Lawandy, Saunderstown, RI (US)

Correspondence Address: KIRKPATRICK & LOCKHART NICHOLSON GRAHAM LLP, STATE STREET FINANCIAL CENTER, ONE LINCOLN STREET, BOSTON, MA, 02111-2950, US

(73) Assignee: Solaris Nanosciences, Inc., Providence, RI (US)

(21) Appl. No.: 11/215,678

(22) Filed: Aug. 29, 2005

Related U.S. Application Data
(60) Provisional application No. 60/679,104, filed on May 9, 2005.

(51) Int. Cl. H01L 31/00

(52) U.S. Cl. 136/263

(57) ABSTRACT

A rechargeable photovoltaic cell. In one embodiment the photovoltaic cell includes a first electrode with a transparent substrate having a porous high surface area titanium dioxide layer thereon, and including a light absorbing dye. The rechargeable cell also includes a second electrode which includes a transparent electrically conductive substrate arranged in spaced apart relationship with the first electrode so as to define a gap with the first electrode. A re-sealable seal provides access to the gap from the exterior of the cell. An electrolyte solution is located within the gap. Another aspect of the invention relates to a method of recharging a photovoltaic cell. In one embodiment the method includes draining the first electrolyte solution from gap in the photovoltaic cell, flushing the first electrolyte solution from the gap, drying the gap, and filling the gap with a second electrolyte solution all through a re-sealable seal.

### RELATED APPLICATIONS

The present application claims priority and incorporates by reference provisional application No. 60/679,104 filed May 9, 2005.

### FIELD OF THE INVENTION

The present invention relates generally to photovoltaic cells and more specifically to dye sensitized photovoltaic cells.

### BACKGROUND OF THE INVENTION

Photovoltaic cells, or solar cells, have long been used as energy sources. Traditional solar cells typically were constructed from a semiconductor, such as silicon. While photovoltaic cells employing semiconductors have proven to be effective energy sources for some applications, their fabrication and maintenance are expensive, making them cost-prohibitive in many applications.

In an effort to provide a more affordable photovoltaic cell, dye-sensitized solar cells (DSSC) were developed utilizing inexpensive, transition metal electrodes incorporating dye-stuffs within the electrode to absorb solar radiation. In such a solar cell the conversion of solar energy into electricity is achieved most efficiently when substantially all the emitted photons with wavelengths below 820 nm are absorbed. Such a solar cell having a porous titanium dioxide substrate with a dye dispersed within the substrate to absorb light in the visible region of the spectrum is disclosed in U.S. Pat. No. 5,350,644 to Graetzel, et al.

DSSCs generally include two spaced apart electrodes and an electrolyte solution. Typically the first electrode includes a transparent conductive substrate coated with a TiO₂ porous matrix which includes a dyestuff. The second or counter electrode is typically a transparent conducting electrode; frequently with a platinum coating. Light passes through the transparent conductive substrate and is absorbed by the dye within the porous matrix When the dye absorbs light, electrons in the dye transition from a ground state to an excited state, in a process known as photoexcitation. The excited electron then can move from the dye to the conduction band in TiO₂ matrix. This electron diffuses across the TiO₂ and reaches the underlying conductive transparent substrate. The electron then passes through the rest of the circuit returning to the second or counter electrode of the cell.

When the electron moves from the dye to the TiO₂, the dye changes oxidation state because it has fewer electrons. Before the dye can absorb another photon of light, the electron must be restored. The electrolyte provides an electron to the dye and in turn has its oxidation state changed. The electrolyte subsequently recovers an electron itself from the second or counter electrode in a redox reaction.

In order for light energy conversion to be efficient, the dyestuff, after having absorbed the light and thereby acquired an energy rich state, must be able to inject, with near unit quantum yield, an electron into the conduction band of the titanium dioxide film. This is facilitated by the dye-stuff being attached to the surface of the TiO₂ through an interlocking group. This group provides the electronic coupling between the chromomorphic group of the dyestuff and the conduction band of the semiconductor. This type of electronic coupling generally requires interlocking, π-conducting substituents such as carboxylate groups, cyano groups, phosphate groups, or chelating groups with π-conducting character, such as oximes, dioximes, hydroxy quinolines, salicylates, and alpha keto enolates.

Dye-sensitized photovoltaic cells, such as those disclosed in Graetzel's patent, have generated substantial interest as viable sources of solar energy because they are easily produced using relatively inexpensive materials, and therefore may be provided at lower cost than traditional semiconductor solar cells. DSSCs however, suffer from several drawbacks impeding their widespread commercial viability.

The primary deficiency is that dye sensitized solar cells (DSSC) are not as durable as semiconductor solar cells. Typically DSSCs remain efficient for only five to ten years. This lack of longevity is generally due to the instability of the electrolyte solution and the dyes in the cell. Specifically durability problems include: the inherent photochemical instability of the sensitizer dye absorbed onto the TiO₂ electrode, as well as its interaction with the surrounding electrolyte; the chemical and photochemical instability of the electrolyte; the instability of the Pt-coating of the counter-electrode in the electrolyte environment; and the nature and the failure of the cell's seals to prevent the intrusion of oxygen and water from the ambient air and the loss of electrolyte solvent.

Further sources of DSSC degradation include photo-chemical or chemical degradation of the dye (such as adsorption of the dye, or replacement of ligands by electrolyte species or residual water molecules), direct band-gap excitation of TiO₂ (holes in the TiO₂ valence band act as strong oxidants), photo-oxidation of the electrolyte solvent, release of protons from the solvent (change in pH), catalytic reactions by TiO₂ and Pt, changes in the surface structure of TiO₂, dissolution of Pt from the counter-electrode, and adsorption of decomposition products onto the TiO₂ surface.

Previously research has focused on developing a better seal to the cell, an electrolyte solution resistant to degradation (several polymer gels have been proposed), and a bleach-resistant dye. Such research has been limited to date in its effectiveness.

The present invention remedies these deficiencies without requiring that new chemical entities be developed.

### SUMMARY OF THE INVENTION

In one aspect the invention relates to a rechargeable photovoltaic cell. In one embodiment the rechargeable cell includes a first electrode with a transparent substrate having a porous high surface area titanium dioxide layer thereon, and including a light absorbing dye. The rechargeable cell also includes a second electrode which includes a transparent electrically conductive substrate arranged in spaced apart relationship with the first electrode so as to define a gap. with the first electrode. A re-sealable seal provides access to the gap from the exterior of the cell. An electrolyte solution is located within the gap.

In one embodiment, the first and second electrodes of the rechargeable photovoltaic cell are planar structures, and a gap is defined between the planar structures. In another embodiment, the rechargeable photovoltaic cell includes a means for flushing the light absorbing dye from the cell by introducing a liquid therein, and for re-introducing the light absorbing dye into the first electrode. The means for flushing the dye may be any apparatus capable of introducing a fluid liquid or gas, which strips the dye from the titania surface, including, but not limited to, a syringe, a pump and tubing with valving, connectors, filters, sensors, etc., and also by removing a seal to a defined cavity or channel in the physical cell structure. The means for re-introducing the dye may be any apparatus capable of introducing a fluid liquid or gas of concentrated dye in a solvent capable of depositing dye on the titania surface, including, but not limited to a syringe, a pump and tubing with valving, connectors, filters, sensors, etc., and by removing a seal to a defined cavity or channel in the physical cell structure.

In another aspect the invention relates to a method of recharging a photovoltaic cell. In one embodiment the method includes includes draining the first electrolyte solution from the gap in the photovoltaic cell, flushing the first electrolyte solution from the gap, drying the gap, and filling the gap with a second electrolyte solution through a re-sealable seal. In another embodiment the recharging method further includes flushing the light absorbing dye with a hypochlorite salt; and re-dyeing the first electrode. In a further non-limiting embodiment, after recharging, the photovoltaic cell may be exposed to visible light. Such exposure may be from a solar simulator for a period of time of from about 15 minutes to about 45 minutes. This has been found to increase photovoltaic performance of the recharged cell.

In another aspect the invention relates to an apparatus for recharging a photovoltaic cell. In one embodiment the apparatus includes a fluid depository, a reservoir containing a fluid; and a pumping means for introducing the fluid into the photovoltaic cell, through a re-sealable seal. In another embodiment, the pumping means introduces a fluid for flushing one of the electrolyte solution, and light absorbing dye from the photovoltaic cell.

### BRIEF DESCRIPTION OF THE DRAWINGS

These and other aspects of the invention are better understood with reference to the detailed description of the invention with reference to the figures in which:

FIG. 1 is a cross-sectional elevational view of an embodiment of a photovoltaic cell of the present invention;

FIG. 2 is a flow chart of an embodiment of the steps of recharging the photovoltaic cell of FIG. 1 according to a method of the invention;

FIG. 3 is a graph of the results of multiple recharging of the cell of FIG. 1 utilizing the method of FIG. 2; and

FIG. 4 is a schematic representation of an embodiment of the recharging apparatus of the invention as disclosed herein.

### DETAILED DESCRIPTION OF THE INVENTION

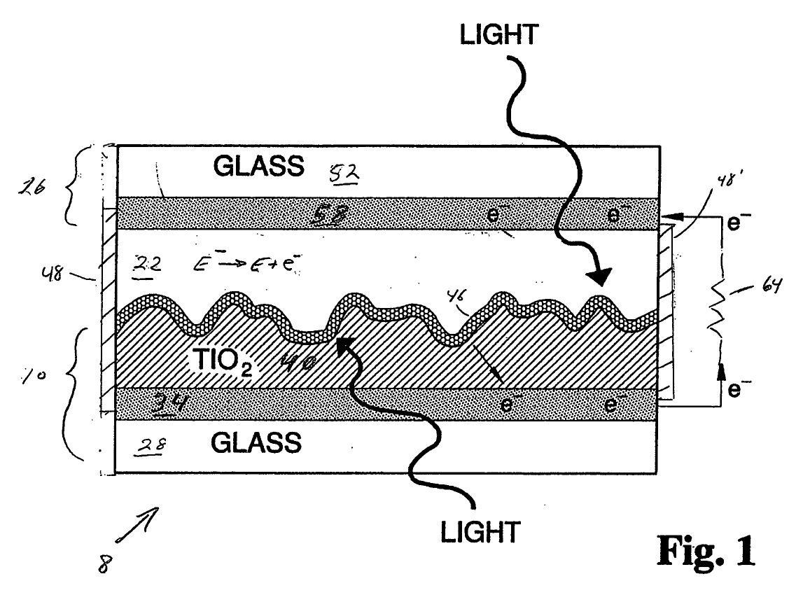

Dye sensitized solar cells are known in the art, and shown in U.S. Pat. No. 5,350,644 to Graetzel, which is incorporated by reference herein. Referring to FIG. 1, a photovoltaic cell 8 constructed in accordance with the invention is shown. The cell 8 generally includes two spaced apart electrodes 10, 16 and an electrolyte solution 22. The first electrode 10 includes a transparent conductive substrate such as glass 28 with a thin conductive film 34 and coated with a TiO₂ porous matrix 40 which includes a dyestuff 46. In one embodiment the dye is N3 (cis-bis (isothiocyanato) bis (2,2-bipyridyl-4, 4′-dicarboxylato)-ruthenium (II)) dissolved in ethanol. The second or counter electrode 16 is typically a transparent conducting electrode of a substrate, such as glass 52 coated with a thin conductive film 58 such as platinum. The gap between the two electrodes 10, 16 is filled with electrolyte 22. In one embodiment the electrolyte 22 is an Iodide electrolyte, such as an iodide based low viscosity electrolyte with 50 mM of tri-iodide. An example of such an electrolyte is solaronix Idolyte PN-50 from Solaronix SA, Rue d l'ouriette 129 CH-1170 Aubonne/Switzerland. The electrolyte 22 is maintained within the gap by a re-sealable seal 48, 48′.

Light passes through the transparent conductive substrates 28, 52 and is absorbed by the dye 46 within the porous matrix 40. When the dye 46 absorbs light, electrons in the dye 46 transition from a ground state to an excited state. The excited electron then can move from the dye 46 to the conduction band in TiO₂ matrix 40. This electron diffuses across the TiO₂ matrix 40 and reaches the underlying conductive transparent substrate 28. The electron then passes through the rest of the circuit 64 returning to the second or counter electrode 58 of the cell. In one embodiment the matrix 40 is nano-crystaline

When the electron moves from the dye 46 to the TiO₂ matrix 40 the dye 46 changes oxidation state and before the dye 46 can absorb another photon of light, the electron must be restored. The electrolyte (E) 22 provides an electron to the dye 46 and has its own oxidation state changed. The electrolyte 22 subsequently recovers an electron from the second or counter electrode 16 in a redox reaction.

In the embodiment shown, the two glass electrodes 10,16 provide two surfaces of the container that holds the electrolyte 22. An elastic material seal 48, 48′ formed to both the electrodes completes the electrolyte 22 holding container. In one embodiment the volume of the cell is 8×10⁻³ cm³. In the embodiment shown, the seal, is an epoxy and acts as a septum which can be penetrated by a hypodermic needle without leaking. In one embodiment the epoxy is Stycast LT from Emerson & Cumming, 46 Manning Road, Billerica, Mass. In other embodiments, closable valves providing access through the seal are contemplated so that fluids can be introduced into and removed from the cell without requiring the seal be penetrated by a needle.

In the embodiment depicted, the dye-stuff is attached to the surface of the TiO₂ through an interlocking group of π-conducting substituents. In various embodiments, suitable substituents include carboxylate groups, cyano groups, phosphate groups, or chelating groups with π-conducting character, such as oximes, dioximes, hydroxy quinolines, salicylates, and alpha keto enolates.

In an embodiment, the TiO₂ is sintered on the first electrode. In an embodiment, the TiO₂ particles may be soaked with an oxidant, such as a sodium hypochlorite solution prior to sintering. In another embodiment, the sodium hypochlorite solution is flushed by introducing a second solution to the substrate after soaking the TiO₂ particles.

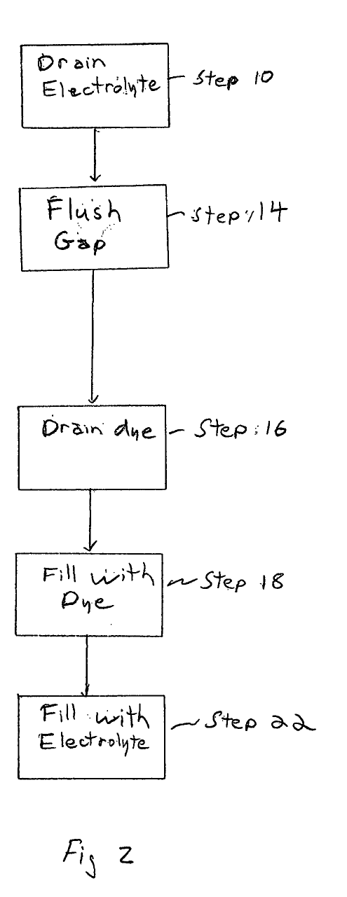

When the performance of the cell degrades over time, the cell can be recharged. A monitor may be used to determine when the cell is below a certain threshold requiring re-charging. Referring also to FIG. 2, the first step (Step 10) is to drain the electrolyte solution. This may be accomplished by inserting a hypodermic needle through the re-sealable seals 48, 48′ and withdrawing the electrolyte 22. In an embodiment, the electrolyte is pushed out of the cell using a suitable solvent, such as acetonitrile, and the electrolyte and solvent are collected at a second port, such as resealable seal 48′. Next (Step 14) the remaining electrolyte 22 is flushed from the cell using acetonitrile. At this point, if only the electrolyte 22 is to be replaced, fresh electrolyte may be introduced into the gap through the re-sealable seal using the hypodermic needle. As used herein, the term flushing refers to the removal of a first substance from an area by the introduction of a second substance which carries the first substance out of the area.

If the dye 46 is also to be replaced, following the flushing of the electrolyte (Step 14), the light absorbing dye 46 is flushed (Step 16) from the matrix 40, using a first flushing solution, such as a hypochlorite salt solution, an aqueous ammonia, a sodium hydroxide solution, and a potassium hydroxide solution. In an embodiment a second flushing solution may be used to flush the first flushing solution. In an embodiment, a new dye may be added without flushing the light absorbing dye. The old dye 46 is then replaced with a fresh dye 46, again through the re-sealable seal 48. In another embodiment, after an amount of time suitable for ensuring dyeing of the titania matrix, excess dye solution may be removed by a third solvent flush. At this time the electrolyte solution 22 can then be introduced into the cell through the re-sealable seal 48.

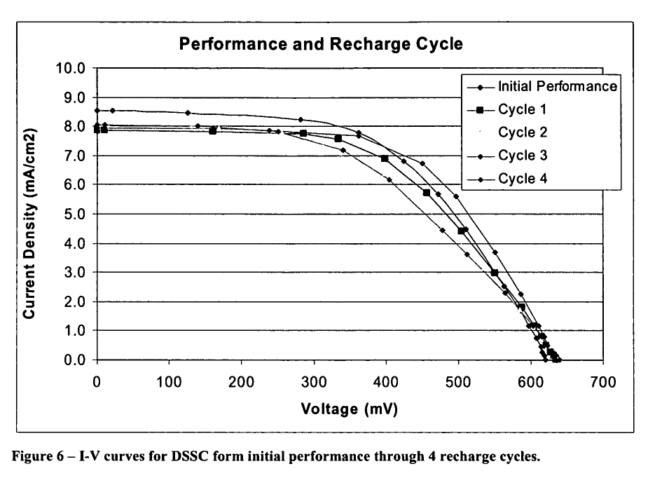

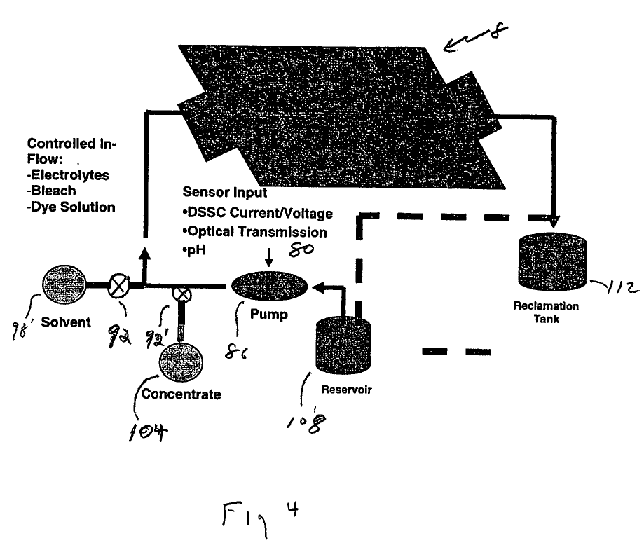

Referring to FIG. 3, a graph of the results of the current density of the cell plotted against voltage over multiple cycles of cleaning and dying is depicted. As can be seen, multiple cycles produce substantially identical results when compared to the initial performance of the cell. Referring to FIG. 4, a continuous system for removing old fluid constituents of the cell and replacement with new constituents is depicted. In the embodiment shown a sensor connected to a processor 80 monitors the conditions in the cell or group of cells 8. Such conditions can include the output current or voltage of the cell, a measure of optical transmission through the cell, or the pH of the cell among other parameters. When the cell's condition is determined to be below a predetermined set point, the processor uses a pump 86 and a series of valves 92 to pump the various solvents, dyes and bleaches from their reservoirs 98, 104, 108 into the cell 8 and remove various components into a reclamation tank 112, in the order as required by the steps of FIG. 2.

Although the invention has been described in terms of its embodiments, one skilled in the art will be aware that certain changes are possible which do not deviate from the spirit of the invention and it is the intent to limit the invention only by the scope of the claims.

What is claimed is:

1. A rechargeable photovoltaic cell comprising:
a first electrode comprising a transparent substrate, a porous high surface area titanium dioxide layer thereon, and a light absorbing dye;
a second electrode comprising a transparent electrically conductive substrate arranged to define a gap with said first electrode;
an electrolyte solution in flowable contact with said first and second electrodes; and
a re-sealable seal forming a fluid tight container in conjunction with the first and second electrode.

2. The rechargeable photovoltaic cell of claim 1 wherein said first and second electrodes comprise planar structures.

3. The rechargeable photovoltaic cell of claim 1 further comprising a means for flushing said light absorbing dye, and means for re-introducing said light absorbing dye in said first electrode.

4. The rechargeable photovoltaic cell of claim 3 wherein said light absorbing dye is flushed with a hypochlorite salt.

5. The rechargeable photovoltaic cell of claim 1 further comprising means for flushing said electrolyte solution, and means for re-introducing said electrolyte solution into said re-sealable gap.

6. The rechargeable photovoltaic cell of claim 1 wherein said light absorbing dye is a ruthenium complex.

7. The rechargeable photovoltaic cell of claim 1 wherein said electrolyte solution is selected from the group of iodide, and triiodide solutions.

8. The rechargeable photovoltaic cell of claim 1 wherein said titanium dioxide layer has been sintered.

9. The rechargeable photovoltaic cell of claim 8 wherein said titanium dioxide layer has been soaked in sodium hypochlorite prior to sintering.

10. A method of recharging a photovoltaic cell comprising a first electrode including a transparent substrate, a porous high surface area titanium dioxide coating, and a light-absorbing dye, a second electrode, and a first electrolyte solution in a gap between said first and second electrode and a re-sealable seal forming a fluid tight container with said first and second transparent electrodes, the method comprising the steps of:
draining said first electrolyte solution from the gap between said first and second electrode through said re-sealable seal,
flushing said gap through the re-sealable seal,
drying said gap through the re-sealable seal, and
filling said gap with a second electrolyte solution through the re-sealable seal.

11. The method of claim 10 further comprising the steps of flushing said light absorbing dye from the first electrode and re-dyeing said first electrode prior to filling said gap with said second electrolyte solution.

12. The method of claim 10 wherein said re-sealable seal comprises a valve.

13. The method of claim 10 wherein said light absorbing dye is ruthenium complex.

14. The method of claim 10 wherein said electrolyte solution is selected from the group of iodide, and triiodide solutions.

15. The method of claim 10 further comprising exposing the photovoltaic cell to visible light.

16. An apparatus for recharging a photovoltaic cell comprising:
i) a rechargeable photovoltaic cell comprising:
a first electrode comprising a transparent substrate, a porous high surface area titanium dioxide layer thereon, and a light absorbing dye;
a second electrode comprising a transparent electrically conductive substrate arranged to define a with said first electrode;
an electrolyte solution in flowable contact with said first and second electrodes; and
a re-sealable seal forming a fluid tight container with the first and second electrodes;
ii) a pump for removing said fluid from said rechargeable photovoltaic cell introducing said fluid into said rechargeable photovoltaic cell; and
iii) a sensor and processor in communication with said rechargeable photovoltaic cell and in communication with said pump,
wherein said processor causes said pump to operate in response to said sensor detecting changes in said conditions of said rechargeable photovoltaic cell.

17. The apparatus for recharging a photovoltaic cell of claim 16 wherein said pumping means introduces a fluid for flushing one of said electrolyte solution, and said light absorbing dye.
